(19) United States
(12) Patent Application Publication
(10) Pub. No.: US 2003/0077869 A1
(43) Pub. Date: Apr. 24, 2003

(54) Semiconductor device and a method of masking

(75) Inventors: Keith Guy Kamekona, Scottsdale, AZ (US); James Robert Morgan, Chandler, AZ (US); Guy Edwin Averett, Mesa, AZ (US); Misbahul Azam, Gilbert, AZ (US); Weizhong Cai, Scottsdale, AZ (US)

Correspondence Address: Lydia McNamara, ON Semiconductor, Patent Administration Dept - MD A230, P.O. Box 62890, Phoenix, AZ, 85082-2890, US

(73) Assignee: Semiconductor Components Industries, LLC.

(21) Appl. No.: 09/982,392

(22) Filed: Oct. 18, 2001

(51) Int. Cl. H01L 21/331; H01L 21/8222

(52) U.S. Cl. 438/309

(57) ABSTRACT

A method of forming a semiconductor device (1000) includes the step of exposing a first region (140) of a semiconductor substrate (101) with a photomask (180). A material is implanted into the first region to form a compound that masks the first region of the semiconductor substrate to form an electrode (155) of the semiconductor device.

### BACKGROUND OF THE INVENTION

The present invention relates in general to semiconductor devices and, more particularly, to a high-speed semiconductor device structure and a method of manufacturing the same.

In modern day electronic industries, high-speed data processing is very important. Circuits must respond to very high input data frequencies. The transistors in high-speed logic circuits should be designed to work at high frequencies as well as high current and power gains. Shrinking the base widths and introducing the use of materials like Silicon-Germanium (Si—Ge) or Silicon-Germanium-Carbon (Si—Ge—C) in the base region has brought significant improvements in the frequency response of the circuit due to the lower energy gap these materials have over a traditional silicon base alone. Transistors formed using Si—Ge are called Heterojunction Bipolar Transistor (HBT), the use of which has increased the operation cut off frequency from about 14 GHz to over 80 GHz.

Current HBT technologies suffer from high cost due to the complex masking processes needed to form active layers in base regions. Base region masks are formed using multiple deposition, photolithographic, and etch steps. A problem is that the masks used in the photolithography equipment to pattern the deposition, etch, and implant are expensive to generate, store and use. Furthermore, different photolithographic masks are often required for implantation, deposition, or etching steps. Depositions are usually carried out at high temperatures, which use up the thermal budget allocated to complete the device and deleteriously effect overall device performance. Cost is further increased as the equipment needed for performing these steps is expensive and occupies a large area of a manufacturing facility.

Hence, there is a need for a method of simplifying the fabrication of an HBT be reducing the number of masking steps.

### BRIEF DESCRIPTION OF THE DRAWINGS

FIG. 1 is a cross-sectional view after a first processing step of one embodiment of a HBT structure;

FIG. 2 is a cross-sectional view of the HBT structure after a second processing step;

FIG. 3 is a cross-sectional view of the HBT structure after a third processing step;

FIG. 4 is a simplified cross-sectional view of the HBT structure after a fourth processing step.

### DETAILED DESCRIPTION OF THE DRAWING

In the figures, elements having the same reference number have similar functionality.

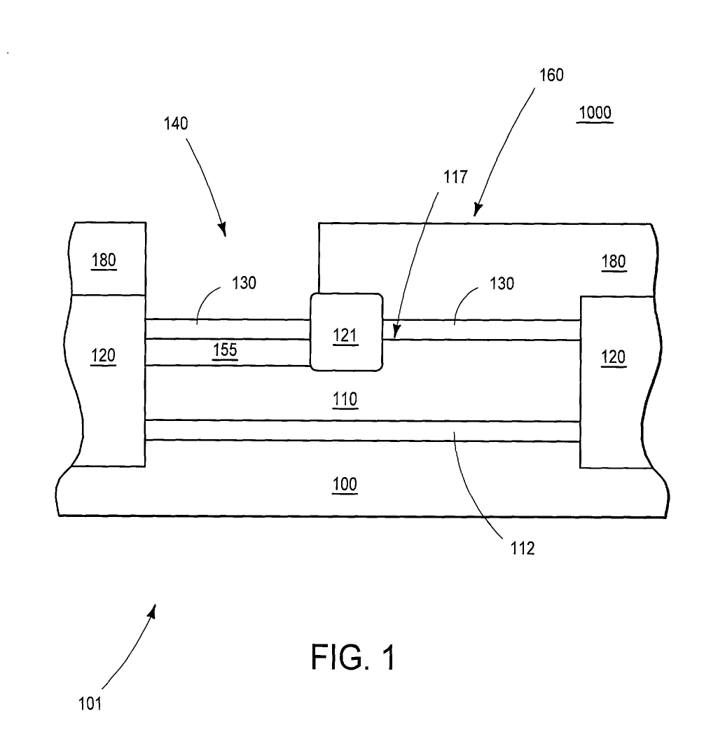

FIG. 1 is a cross section of one embodiment of a HBT structure 1000 formed with various processing on a base layer 100 of a semiconductor substrate 101. In one embodiment, base layer 100 is formed to have a p-type conductivity and a doping concentration of 2.4×10¹⁷ atoms per centimeter cubed (cm⁻³).

A layer 110 is an N— epitaxial silicon approximately one micron thick. Layer 110 has a resistivity of 0.284 ohm-cm.

Layer 110 is formed over a layer 112, which has an n-type conductivity and a high doping concentration to produce a low resistance. In one embodiment, layer 112 is formed as a buried layer. In an alternative embodiment, layer 112 is formed as an epitaxial layer.

Regions 120 comprise isolation regions for electrically isolating HBT structure 1000 from other devices (not shown) on base layer 100. In one embodiment, regions 120 are formed with silicon dioxide.

A region 121 functions as an isolation region for electrically isolating portions of HBT structure 1000 from each other. In one embodiment, region 121 is formed with silicon dioxide.

A layer 130 is formed by thermally growing silicon dioxide approximately 500 angstroms thick, which covers a base region 160 and a collector region 140 of HBT structure 1000. In one embodiment, layer 130 covers bottom surfaces of trenches formed in base region 160 and collector region 140. Layer 130 is formed to protect a surface 117 of layer 110 in base region 160 from mechanical damage and/or contamination from photomasking processes. An active portion of HBT structure 1000 is formed in base region 160. Where such damage is not a concern, layer 130 is not used.

Note that, depending on the application, base layer 100 may alternatively include other films, materials or doping areas which are not shown in order to simplify the description.

An implant mask 180 formed with photolithography masking material is deposited over HBT structure 1000, patterned and exposed to light so as to harden portions of the photolithography masking material. The photolithography masking material that is not hardened is then removed using typical wet or dry etching methods.

Next, using implant mask 180, a layer 155 is formed by a first implant step, which introduces n-type dopants through layer 130 to produce collector region 140 as an N— collector. In one embodiment, the implant is performed using approximately 5×10¹⁴ atoms per centimeter cubed (cm⁻³) phosphorus (P) species at about 180 keV.

A second implant step is then performed using implant mask 180 to introduce an oxygen species of approximately 2'10¹⁶ atoms per centimeter cubed (cm⁻¹) O₂ at about 80 keV into collector region 140 to produce elemental oxygen in layers 130 and 155.

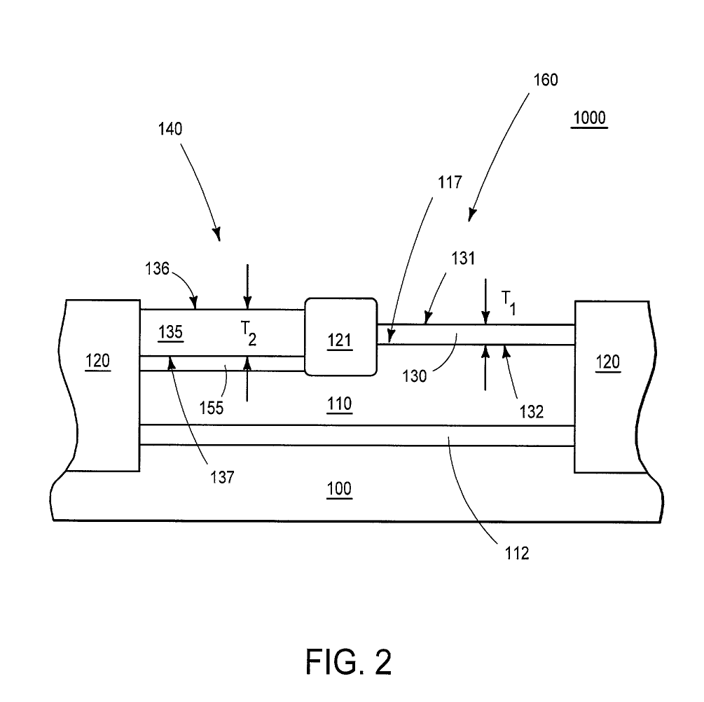

FIG. 2 depicts HBT structure 1000 after a second processing step. Implant mask 180 is removed using a standard photoresist removal process.

A rapid thermal anneal (RTA) step of approximately one minute thirty seconds at a temperature of about one-thousand and twenty degrees centigrade is applied to HBT structure 1000. The RTA step is used to react the implanted elemental oxygen in collector region 140 with semiconductor material from layer 155 to form a compound of silicon dioxide which combines with layer 130 to form an oxide 135. As a result, oxide 135 has a thickness T2 that is greater than the thickness T1 of layer 130. The increased thickness of oxide 135 results in the plane of upper surface 136 of oxide 135 being higher than the plane of upper surface 131 of layer 130. Similarly, the plane of lower surface 137 of oxide 135 is lower than the plane of lower surface 132 of layer 130. The reaction of implanted oxygen with the semiconductor material of layer 155 consumes a portion of layer 155 to reduce the distance between layer 155 and layer 112, effectively shortening the conduction path to reduce the resistance from layer 112 to layer 155.

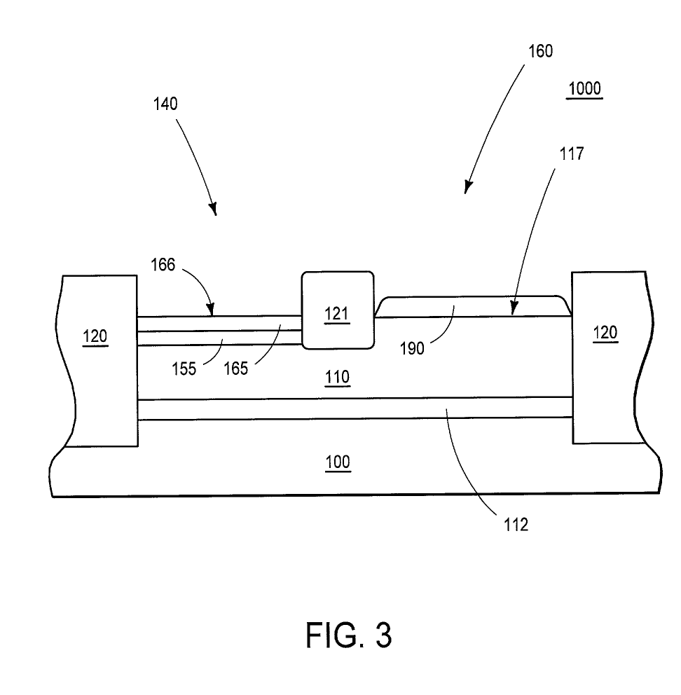

FIG. 3 depicts HBT structure 1000 after a third processing step. HBT structure 1000 is subjected to an unmasked etch step to remove layer 130 from base region 160 while leaving a portion of oxide 135 in collector region 140 as a mask oxide 165. In one embodiment, the etch step is a timed etch process that removes a predetermined thickness of silicon dioxide to leave approximately 400 Angstroms of mask oxide 165 in collector region 140. Alternatively, the etch step can utilize endpoint and/or species detection to stop the etch after layer 130 is cleared but before oxide 135 is completely removed.

Once layer 130 is cleared from base region 160, a layer of monocrystalline silicon-germanium (Si—Ge) referred to as Si—Ge 190 is deposited on layer 110 in base region 160 to a thickness of approximately 1500 Angstroms. The deposition is performed at a low pressure so that the stronger molecular bonds present on monocrystalline silicon surfaces cause Si—Ge molecules to adhere and form a monocrystalline epitaxial film, while the Si—Ge molecules do not adhere to the weaker bonds on polycrystalline or amorphous surfaces. For example, surface 117 is a monocrystalline silicon surface to which Si—Ge molecules adhere to form Si—Ge 190. In contrast, a surface 166 of mask oxide 165 is an amorphous surface that forms a weaker bond to which the Si—Ge molecules fail to attach. In effect, mask oxide 165 rejects the deposition of Si—Ge.

In one embodiment, Si—Ge 190 is formed to a thickness of about one thousand one hundred Angstroms. Si—Ge 190 has a p-type conductivity and a doping concentration of about 2×10¹⁹ atoms per centimeter cubed (cm⁻¹).

Note that Si—Ge 190 is selectively formed in base region 160 but is not formed elsewhere. The described method allows a selective deposition of an epitaxial film to be achieved by using a single photomask to pattern both base region 160 and collector region 140.

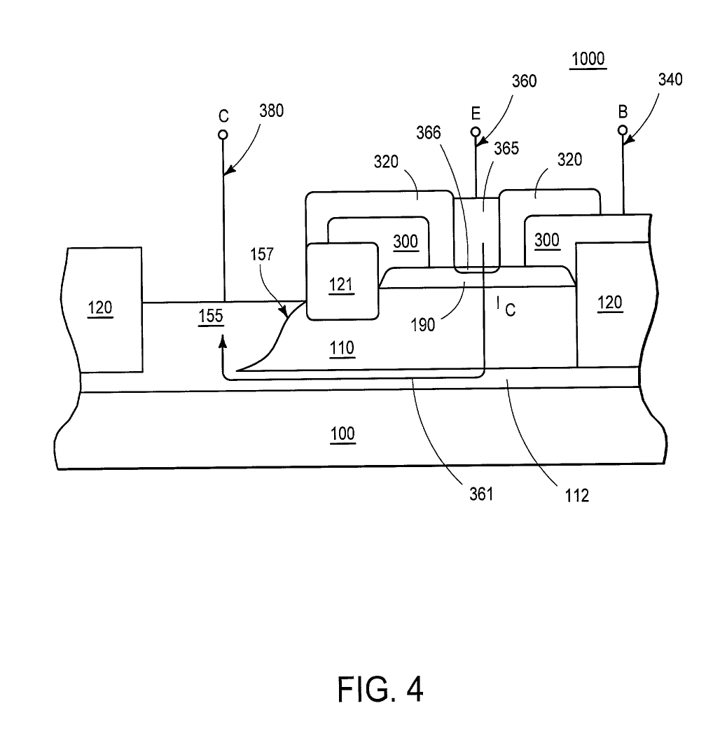

FIG. 4 is a cross-sectional view of HBT structure 1000 after a fourth processing step.

An emitter 366 is formed over Si—Ge 190 with silicon to a thickness of about four hundred Angstroms. In one embodiment, emitter 366 is formed with monocrystalline silicon and is heavily doped to have an n-type conductivity and a doping concentration of about 1×10²⁰ atoms per centimeter cubed (cm⁻¹). Emitter 366 typically is formed in a standard epitaxial reactor programmed to produce Si—Ge 190 and emitter 366 in a single processing step.

A conductive material such as polysilicon is deposited on HBT structure 1000 and patterned to produce a layer 300 that contacts Si—Ge 190 as shown. Layer 300, Si—Ge 190 and a metal trace functioning as a base electrode 340 comprise the base of HBT structure 1000.

A dielectric material is deposited on HBT structure 1000 and patterned to produce a dielectric layer 320 as shown. In one embodiment, layer 320 is formed with Nitride to a thickness of approximately 1000 Angstroms.

A conductive material such as doped polysilicon is deposited and patterned to produce a plug 365 that contacts emitter 366 and is isolated from layer 300 by layer 320. An emitter electrode 360 provides an external connection to emitter 366 via plug 365. Plug 365, emitter 366 and emitter electrode 360 function as the emitter of HBT structure 1000.

A collector electrode 380 provides an external connection to layer 155. Collector electrode and layer 155 function as the collector of HBT structure 1000. In one embodiment, thermal cycles needed to produce layer 300, layer 320 and/or plug 365 result in layer 155 outdiffusing into surrounding region 110 to increase the depth and width of layer 155, producing a non-parallel side 157.

In operation, base electrode 340 provides a means to apply a bias to the base of HET structure 1000 that allows a collector current 361 to flow. Collector current 361 flows from emitter electrode 360 through plug 365, through emitter 366, Si—Ge 190, N— epitaxial region 110, buried layer 112, layer 155, and to collector electrode 380.

As an alternate method, the processes described above are the same except that layer 155 is implanted after Si—Ge is formed. That is, using implant mask 180, perform the oxygen implant. Then, remove implant mask 180 and perform the RTA anneal to produce the thicker oxide 135. Then perform the timed etch described above to clear layer 130 from base region 160 while producing mask oxide 165 in collector region 140. Selective Si—Ge 190 is then deposited in base region 160. Next, implant mask 180 is again formed and then used to pattern the implant of n-type dopants into collector region 140 to form layer 155.

In summary, the above-described invention provides a simpler, more cost effective method of making a semiconductor device by reducing the number of photomasking steps. A photomask exposes a first region of a semiconductor device. A material is implanted into the first region to form a compound that masks a first electrode of the semiconductor device. Hence, a single photomask step is used to both expose a region of a semiconductor device and to form a mask in the same region, thereby avoiding the need for a second photomask or photolithography step.

What is claimed is:

1. A method of forming a semiconductor device, comprising the step of implanting a material into a first region of a semiconductor substrate to form a compound that masks the first region.

2. The method of claim 1, wherein the step of implanting includes the step of implanting a material selected from the group consisting of oxygen, nitrogen and fluorine.

3. The method of claim 1, further comprising the step of annealing the semiconductor substrate to induce a reaction between the material and the semiconductor substrate that forms the compound.

4. The method of claim 3, wherein the step of annealing includes the step of heating the semiconductor substrate to produce the compound as a dielectric material.

5. The method of claim 4, wherein the step of heating includes the step of forming the dielectric material as silicon dioxide.

6. The method of claim 1, wherein the semiconductor substrate is formed with a first semiconductor material, further comprising the step of depositing a second semiconductor materialon a second region of the semiconductor substrate to form an active portion of the semiconductor device.

7. The method of claim 6, wherein the step of depositing includes the step of depositing the second semiconductor material on monocrystalline silicon.

8. The method of claim 7, wherein the step of depositing the second semiconductor material on monocrystalline silicon includes the step of forming the second semiconductor material with a monocrystalline structure to produce a second electrode of the semiconductor device.

9. The method of claim 8, wherein the step of forming includes the step of forming an emitter of a heterojunction bipolar transistor (HBT) and the step of implanting a material into a first region includes the step of forming a collector of the HBT.

10. The method of claim 1, wherein the compound is formed to a first thickness, further comprising the steps of:
forming a dielectric layer having a second thickness in the second region, where the second thickness is less than the first thickness; and
etching the semiconductor substrate to remove the dielectric layer from the second region while leaving a portion of the compound in the first region.

11. The method of claim 10, wherein the step of forming a dielectric layer includes the step of forming silicon dioxide, and the step of implanting includes the step of forming the compound as silicon dioxide.

12. The method of claim 10, wherein the step of etching the semiconductor substrate includes the method of using endpoint species detection or timed etching to stop the etching process when the semiconductor substrate in the second region is fully exposed.

13. The method of claim 1, further comprising the step of applying a photomask to the semiconductor substrate to expose the first region.

14. A method of making a semiconductor device, comprising the steps of:
forming an oxide layer of a first thickness in first and second regions of a semiconductor substrate;
implanting the first region to increase a thickness of the oxide layer in the first region; and
etching the semiconductor substrate to expose the second region while leaving a portion of the oxide layer in the first region.

15. The method of claim 14, further comprising the step of depositing a semiconductor material on the semiconductor substrate to form a monocrystalline layer in the second region that functions as an active portion of the semiconductor device.

16. A method of forming a mask, comprising the steps of:
implanting a first region of a semiconductor substrate with a material; and
annealing the semiconductor substrate to form a compound with the material to mask the first region.

17. The method of claim 16, wherein the step of annealing includes the step of reacting the material with the semiconductor substrate to form the compound.

18. The method of claim 17, wherein the step of annealing includes the step of reacting oxygen with silicon from the semiconductor substrate to form the compound as silicon dioxide.

19. A method of making a semiconductor device, comprising the steps of:
implanting a material to form a mask over a first region of a semiconductor substrate;
forming an active portion of the semiconductor device in a second region of the semiconductor substrate; and
removing the mask to form an electrode of the semiconductor device for coupling to the active portion.

20. The method of claim 19, wherein the step of implanting a material to form a mask includes the step of forming an oxide over the first region.

21. The method of claim 19, wherein the step of forming an active region of the semiconductor device includes the step of depositing a material selected from the group consisting of silicon-germanium and silicon-germanium-carbon.

22. The method of claim 19, further comprising the steps of:
forming a dielectric layer over the semiconductor substrate before implanting the material; and
etching the semiconductor substrate to remove the dielectric layer from the second region, where a portion of the mask remains to cover the first region.
